(19) United States
(12) Patent Application Publication
(10) Pub. No.: US 2002/0109564 A1
(43) Pub. Date: Aug. 15, 2002

(54) Bulk acoustic wave filter and its package

(75) Inventors: Shu-Hui Tsai, Hsin-Chu City (TW); Chengkuo Lee, Hsin-Chu City (TW); Kuan-Jen Fang, Tainan (TW); Ju-Mei Lu, Ma-Kung City (TW)

Correspondence Address: BRUCE H. TROXELL, SUITE 1404, 5205 LEESBURG PIKE, FALLS CHURCH, VA, 22041, US

(73) Assignee: ASIA PACIFIC MICROSYSTEM, INC.

(21) Appl. No.: 10/043,313

(22) Filed: Jan. 14, 2002

(30) Foreign Application Priority Data
Feb. 9, 2001 (TW) 090102857

(51) Int. Cl. H03H 9/00

(52) U.S. Cl. 333/187

(57) ABSTRACT

A bulk acoustic wave filter device and its package. The filter devices greatly decreases the manufacturing process complexity by the coplanar electrode layout, and it omits the process steps of forming via hole of connectors, such that it is convenient to the coplanar high frequency on-wafer measurement and trimming. Furthermore, by using the wafer level chip scale package (WLCSP) technique, which to integrate the series resonator and the shunt resonator can be integrated, the spaces of filter can be saved and the cost of package can be down.

### BACKGROUND OF THE INVENTION

1. Field of the invention

The invention relates to a bulk acoustic wave filter device and its package. Particularly to the filter uses the coplanar electrode layout and the wafer level chip scale package (WLCSP) technique so as to save the filter spaces and cost down the package.

2. Description of the prior art

The mobile communication is so vigorous development that speed up the requirement of the high frequency wireless electronic device. The mobile ability of the wireless communication product is depended on the size of device and the lifetime of battery. Also the devices manufacturers are dedicated to develop the tiny, cheaper and the more well performance devices. The final step to miniaturize the device is to integrate it with the IC to form a system on a chip (SOC). Presently, in the high frequency front-end of the wireless system, one of the devices that still can not be integrated with the IC, is high frequency front-end filters. In the future, the high frequency front-end filters will be the occupied space and the necessary device in the double, triple or multiple bands standards. The multiplexer obtained by associating the high frequency switch with high frequency front-end filters would be the key to decide the communication quality.

The high frequency front-end filter belongs to the surface acoustic wave filter is more ordinarily used. In the past, the surface acoustic wave filter is not only to be the high frequency front-end filter but also to be the channel-selecting filters in the mid-frequency (IF) band. But to accompany with the development of the direct conversion technique (that is, the zero-IF or near zero-IF technique), it does not need any IF filter, so the application to the surface acoustic wave filter is extended to the high frequency filter. But the surface acoustic wave filter itself has the larger insertion loss and it has worse power dissipation. In the past, it is not rigorous about the insertion loss standard in the use of the mid-frequency channel-selecting filters, and it belongs to the high frequency back-end so that it is not necessary to use a well power dissipation stand. But now, if it is used in the high frequency front-end, the aforementioned both standards will be the problem to the surface acoustic wave filter.

In order to solve the problem, the Sumitomo Electric company in Japan present the growing inter-digital transducer (IDT) electrode on the Zinc Oxide/Diamond/Silicon substrate. It used the high spring constant and well thermal conductivity of the Diamond, so the inter-digital transducer (IDT) electrode on the compound substrate could stand about 35 dBm dissipation and still could maintain the well linearity. But it is rather expensive about the Diamond substrate, and the line pitch of the across finger electrode is below micrometer, and it has the lower tolerance and expensive in the equipment investment.

The other product of the high frequency filter is the Low Temperature Collective Ceramic (LTCC). The Low Temperature Collective Ceramic (LTCC) owns the best benefit of power durability in high frequency. However, it still has else problems that have to be solved, such as: the difficulty in measurement, and not ease to get the ceramic powder from the upper company, and the ceramic happened the shrinkage phenomenon in the manufacturing processes that the deviations of products were caused and it is difficult for trimming.

Recently, the technique about the bulk acoustic wave filter device, such as the Film Bulk Acoustic Resonator (FBAR) device (reference the U.S. Pat. No. 6,060,818) developed by HP company, and the Stack Bulk Acoustic Resonator (SBAR) device (reference the U.S. Pat. No. 5,872,493) developed by Nokia company, which could diminish the volume of the high efficiency filter product, and it could operate in 400 MHz to 10 GHz frequency band. The duplexer using in the CDMA mobile phone is one kind of the filter product. The size of the bulk acoustic wave filter is just a part to the ceramic diplexer, and it owns the better rejection, insertion loss, and power management ability than the surface acoustic wave filter. Those property combinations could make the manufacturer produce the high performance, up-to-date, and mini-type wireless mobile communication equipment. The bulk acoustic wave filter is a semiconductor technique, so it could integrate the filter into the RFIC, and then to be the system in a package (SIP) or the system on a chip (SOC).

Although the SBAR device is not necessary to form a cavity architecture below the bottom of resonator, but it has to deposit the multi-layer film that is difficulty in the process and detrimental to the integration, and it is limited to be selected as the Bragg reflection layer material, so the yield of the device is relative low.

The FBAR device is necessary to form a cavity below the resonator. FIG. 1 is shows a filter device of FBAR type bulk acoustic wave filter multiplexer that is patented as U.S. Pat. No. 5,185,589 by the U.S. Western House Company. Referring to FIG. 1, the three stages bulk acoustic wave filter is including the substrate parts 10, 10′, and 10″. The first piezoelectric layers 12, 12′, 12″ to be used as the first bulk acoustic wave resonator are placed in between the first lower electrodes 11, 11′, 11″ and the first upper electrodes 13, 13′, 13″ respectively. In addition, the second piezoelectric layers 16, 16′, 16″ to be used as the second bulk acoustic wave resonator are placed in between the second lower electrodes 15, 15′, 15″ and the second upper electrodes 17, 17′, 17″ respectively. The first bulk acoustic wave resonator involves the cavity 19, 19′, and 19″. The connections between the first bulk acoustic wave resonator and the second bulk acoustic wave resonator are by means of the metal via holes 18, 18′, and 18″. And the parts that are not necessary to be connected between first bulk acoustic wave resonator and the second bulk acoustic wave resonator are separated by the isolation layers 14, 14′, 14″. Owing to the FBAR device is necessary to form the cavity structure below the resonator bottom, the general mature method is to use the backside etching or the front-side etching substrate to form the cavity structure. In case of adopting the semi-conductor device or the traditional device package, such as the surface mount technology (SMT), the dual in line (DIP), the metal can, or the TO can etc., which must advance be diced, package, and then testing. Because of its specialty of structure, the devices will be damaged and the yield will be lowered if it is diced without protection to it. And in the high frequency device, as there has the high frequency parasitic effect by the package, if the die can be packaged in advance and then after to make a high frequency measurement that will obtain the more correct high frequency parameters. In general, if the test process is performed after the dicing, package, then it is unable to make a coplanar on-wafer RF measurement that is a much save time and cost. Besides, if it makes a full on-wafer trimming, then it is also rather time-consuming and impossible.

### SUMMARY OF THE INVENTION

The one object of the present invention is to improve the defect of the conventional art.

The other object of the present invention is to provide a method fabricating a bulk acoustic wave filter where the electrode upon it coplanar, so that the high frequency measuring and package would be conveniently performed.

Another object of the present invention is to provide a method to manufacture and package the bulk acoustic wave filters that would increase the yield and could measure the high frequency characteristics including the package parasitic effect quickly and accurately.

The again another object of the present invention is to provide a method to manufacture and package the bulk acoustic wave filters that could decrease the dicing damaging rate and could protect the floating structure of the filter, such that the high frequency property would not be affected.

The more again another object of the present invention is to provide a method to manufacture and package the bulk acoustic wave filters that could perform the high frequency on-wafer measurement before and after packaging, and the time and cost to the package and test time would be greatly decreased.

To accomplish the above description object, one embodiment of the bulk acoustic wave filters of present invention is to use the even order ladder-type or lattice-type filter construction, to provide the coplanar electrode to benefit the high frequency on-wafer measurement and package.

To accomplish the above description object, another embodiment of the bulk acoustic wave filters of the present invention is to use the hybrid of Coplanar waveguide line (CPW) and microstrip line, to provide the coplanar electrode to decrease the noise and improve the high frequency filter performance and benefit the high frequency on-wafer measurement and package.

To accomplish the above description object, in the method of packing and manufacturing the bulk acoustic wave filter of present invention, the wafer level chip scale package (WLCSP) technique is used to protect the device before dicing, then the damage to the device is substantially reduced, and the yield is substantially increased.

To accomplish the above description object, in the method of packing and manufacturing the bulk acoustic wave filter of present invention, the wafer level chip scale package (WLCSP) technique is used for integrating the series resonator and the shunt resonator so as to save the filter spaces and cost down the package.

The present invention will be better understood and its numerous objects and advantages will become apparent to those skilled in the art by referencing to the following drawings.

### BRIEF DESCRIPTION OF THE DRAWINGS

FIG. 1 shows an example of a conventional multi-stage bulk acoustic wave filter.

FIG. 2a and the FIG. 2b show a first embodiment of the present invention, wherein by using the series and shunt structure of the even order ladder-type filter the coplanar electrode is then provided.

FIG. 3 shows a second embodiment of the present invention, wherein by using the series and shunt structure of the even order ladder-type filter, the coplanar electrode is then provided.

FIG. 4 shows a third embodiment of the present invention, wherein by using the four resonators of the series and shunt combinations to constitute the lattice filter the coplanar electrode is then provided.

FIG. 5 shows a fourth embodiment of present invention, wherein by using the hybrid of CPW and microstrip line to constitute the two stage ladder-type filter structure, then the coplanar electrode is provided.

FIG. 6 shows a fifth embodiment of present invention, wherein by using the hybrid of CPW and microstrip line to constitute the four stage ladder-type filter structure, then the coplanar electrode is provided.

FIG. 7 shows a flow chart relating to using the wafer level chip scale package (WLCSP) technique in the bulk acoustic wave filter device of present application.

FIG. 8 shows a sixth embodiment of present invention wherein the wafer level chip scale package (WLCSP) technique is used for constituting the bulk acoustic wave filter structure.

FIG. 9 shows a cross-sectional structure along the line AA′ and BB′ to the seventh embodiment using in the wafer level chip scale package (WLCSP) technique combining with the series resonator and the shunt resonator to constitute the bulk acoustic wave filter architecture of present invention.

FIG. 10 shows a cross-sectional structure along the line CC′ using the wafer level chip scale package (WLCSP) technique combining with the series resonator and the shunt resonator to constitute the bulk acoustic wave filter architecture of present invention.

FIG. 11 shows a cross-sectional view to the eighth embodiment using the wafer level chip scale package (WLCSP) technique to combine with the series resonator and the shunt resonator to constitute the bulk acoustic wave filter architecture of present invention and to trim.

### DETAILED DESCRIPTION OF THE PREFERRED EMBODIMENT

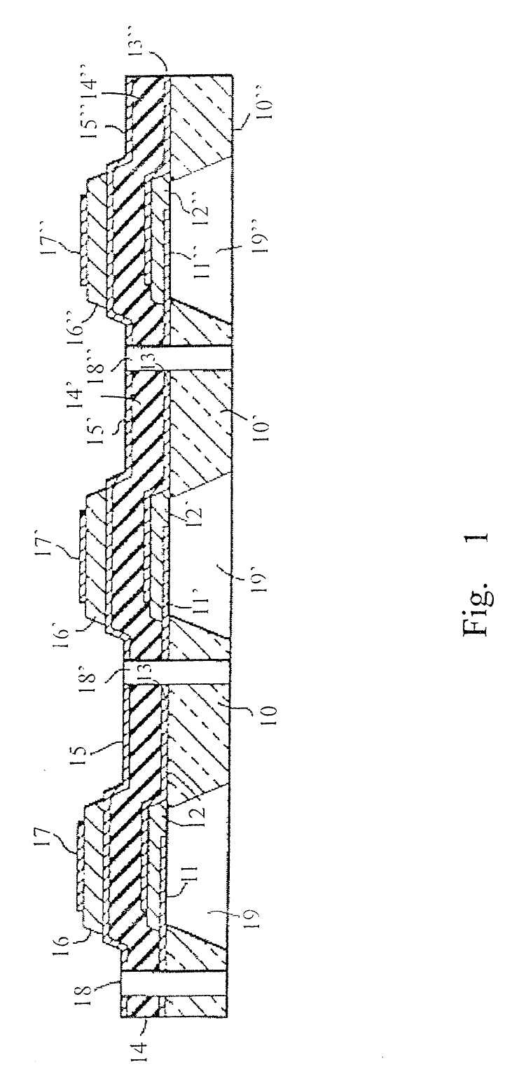

The FIG. 1 is the conventional skill relating to the multi-stage bulk acoustic wave filter that is describing above; it is not repeated here.

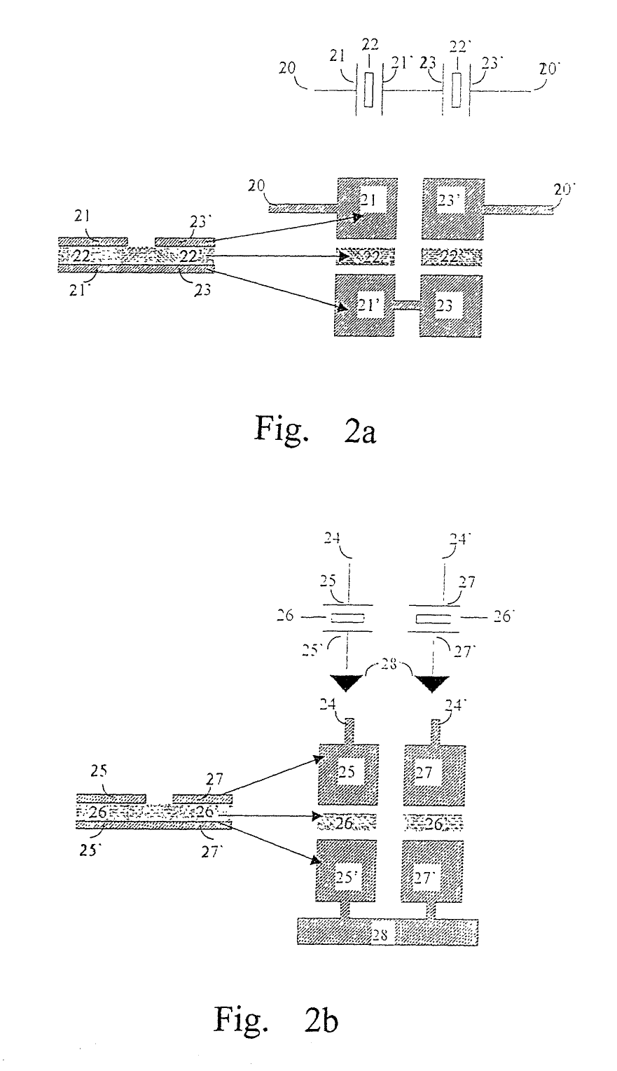

The FIG. 2a and the FIG. 2b are the first embodiment of the present invention, wherein the series and shunt structure of the even order ladder-type filter is used for providing the coplanar electrode. The FIG. 2 shows the two resonators in series.

The left side of the FIG. 2a is the cross-sectional view of the filter device of present invention, referring to the figure, it is shown that the filter device is divided into three layers from the top to bottom: the first layers are the lower electrode layers 21′ and 23, and the second layers are the piezoelectric units 22 and 22′, and the third layers are the upper electrode layers 21 and 23′. The right lower figure of the FIG. 2a is the each layer's dissection corresponding to the filter device, which is explicitly showing the electrodes' outlines and their connections. The right upper figure shows the series filter unit circuit. The operation of full filter is described as follow: the signal is input to the input port 20, and passing the first resonator that is formed with the upper electrode 21, the first piezoelectric unit 22 and the lower electrode 21′, and by the connectivity with the lower electrode 21′ and the lower electrode 23 to the second resonator formed with lower electrode 23, the second piezoelectric unit 22′ and the upper electrode 23′ to attain the series between the first resonator and the second resonator, and make sure the input port 20 and the output port 20′ are laid in the same layer to benefit the back-end process or package and the wafer level measurement.

The FIG. 2b shows the two resonators connected in parallel. The left figure of the FIG. 2a is a side view of the filter device, referring to the figure it can be seen that the filter device is divided into three layers from the top to bottom: the first layers are the lower electrode layers 25′ and 27′, and the second layers are the piezoelectric units 26 and 26′, and the third layers are the upper electrode layers 25 and 27′. The right lower figure of the FIG. 2a is the each layer's dissection corresponding to the filter device, which is shows the electrode outlines and connections. The right upper figure shows the shunt filter unit circuit. The operation of full filter is described as follows: the signal is input to the first connection 24, and passing the connection ground 28 of the third resonator formed with the upper electrode 25, the third piezoelectric unit 26 and the lower electrode 25′, and then input to the second connector 24′, passing by the connection ground of the fourth resonator formed with the upper electrode 27, the fourth piezoelectric unit 26′ and the lower electrode 27′ to attain the shunt connection of the third resonator and the fourth resonator, and make sure the first connector 24 and the second connector are laid in the same layer to benefit the back-end process or package and the wafer level measurement.

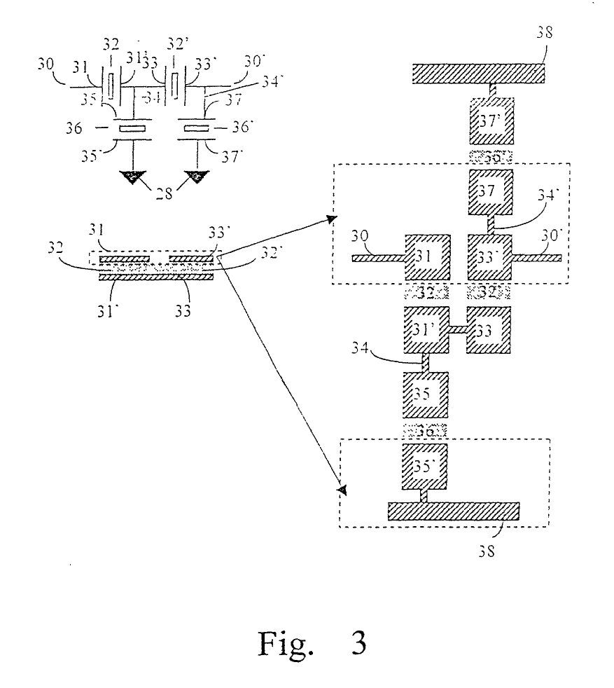

The FIG. 3 shows the four resonators connected in series and shunt to constitute a two stages ladder-type filter. The left lower figure of the FIG. 3 is the side view of the filter device, referring to the figure, it can been seen that the filter device is divided into three layers from the top to bottom: the first layers are the lower electrode layers 31′, 33′ and the lower electrode layers 37′, 35 shown in the right figure; the second layers are the piezoelectric units 32 and 32′, and the layers 36 and 36′ shown in the right figure, and the third layers are the upper electrode layers 31 and 33′. The figure on the right side is the each layer's dissection corresponding to the filter device, which is explicitly showing the electrode outlines and connections. The left upper figure shows the parallel-connected filter unit circuit. The separation of full filter is described as follows: the signal is input to the input port 30, and passing the first resonator formed with the upper electrode 31, the first piezoelectric unit 32 and the lower electrode 31′, and then connect to ground by passing the third resonator formed with the first connector 34, the lower electrode 35, the third piezoelectric unit 36 and the upper electrode 35′. In addition, the first resonator could connect in series with the second resonator formed with the lower electrode 33, the second piezoelectric unit 32′ and the upper electrode 33′, and then connect to ground by passing the fourth resonator formed with the second connector 34′, the upper electrode 37, the fourth piezoelectric unit 36′ and the lower electrode 37′. Then to attain the series connection between the first resonator and the second resonator and the shunt connection of the third resonator and the fourth resonator, and make sure that the input port 30 and the output port 30′ are laid in the same layer to benefit the back-end process or package and the wafer level measurement.

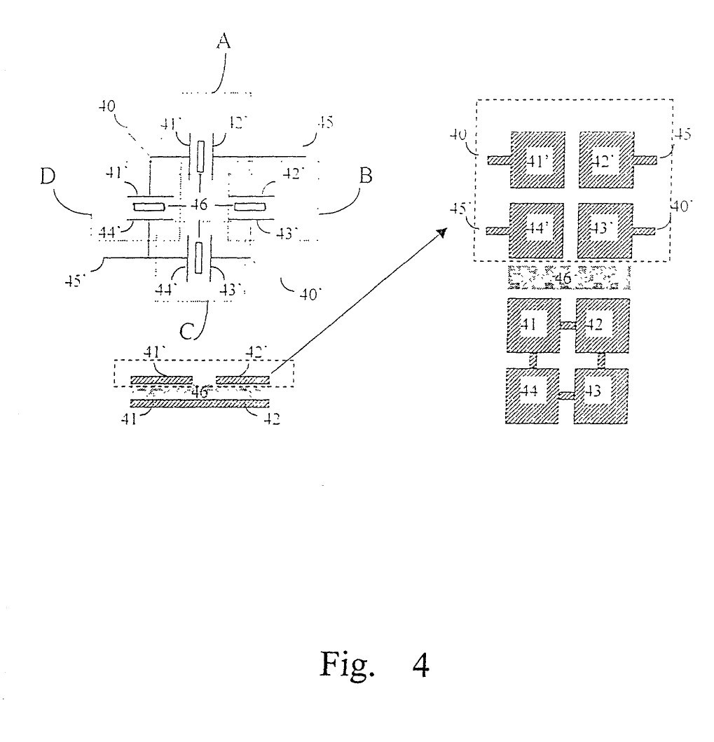

The FIG. 4 shows the four resonators connected in series and shunt to constitute a lattice filter. The left lower figure of the FIG. 4 is the side view of the filter device, referring to the figure, it can been seen that the filter device is divided into three layers from the top to bottom: the first layers are the lower electrode layers 41 and 42 and the lower electrode layer 37′, 35 shown in the right figure; the second layer is the piezoelectric units 46, and the third layers are the upper electrode layers 41′ and 42′, and the layers 43′ and 44′ that are not shown the side views. The figure on the right side is the each layer's dissection corresponding to the filter device, which is explicitly showing to depict the electrode outlines and connections. The left upper figure shows the parallel-connected filter unit circuit. The operation of full filter is described as follows: the signal is input to the input port 40, and passing the first resonator A formed with the upper electrode 41′, the piezoelectric layer 46, the lower electrode 41 and 42, the piezoelectric layer 46 and back to the upper electrode 42′, then the output port 45 is provided. And by passing the second resonator B formed with the upper electrode 42′, the piezoelectric layer 46, the lower electrode 42 and 43, the piezoelectric layer 46 and back to the upper electrode 43′, then an output port 40′ is provided. And then, by passing the third resonator C formed with the upper electrode 43′, the piezoelectric layer 46, the lower electrode 43 and 44, the piezoelectric layer 46 and back to the upper electrode 44′, then the output port 45′ is provided. And finally passing the fourth resonator D formed with the upper electrode 44′, the piezoelectric layer 46, the lower electrode 44, the piezoelectric layer 46 and back to the upper electrode 41′, the output port 40 is provided. The input and the output of full lattice filter laid in the same layer to benefit the back-end process or package and the wafer level measurement.

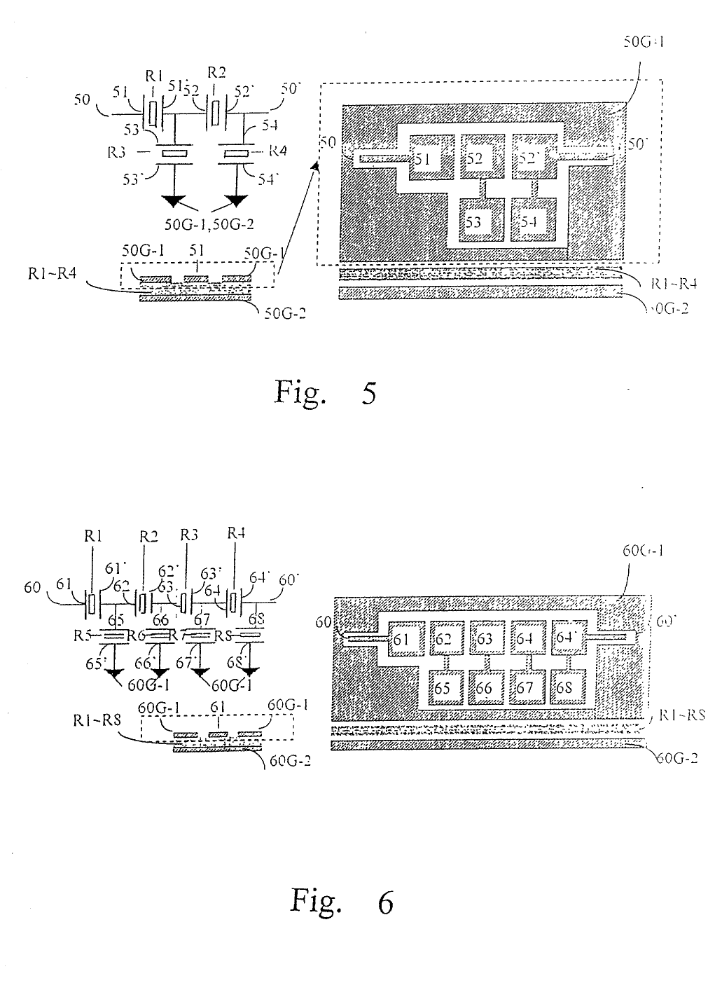

FIG. 5 shows the fourth embodiment of present invention, wherein the hybrid of CPW and microstrip line is used for constituting a two stage ladder-type filter construction, such that the coplanar electrode is provided. The left lower figure of the FIG. 5 is the side view of the filter device, referring to the figure, it is shown that the filter device is divided into three layers from the top to bottom: the first layers are the shielding ground electrode layer 50G-2, the second layers are the piezoelectric units R1, R2, R3 and R4, and the third layers are the upper electrode layers composed with the signal electrode 51 and the two sides ground electrode 50G-1 that both are coplanar transmission line structure. The right figure of the FIG. 5 shows the each layer's dissection corresponding to the filter device, which is explicitly showing the electrode outline and connection. Referring to the side view, it can been seen that the signal electrode 51 and the two sides ground electrode 50G-1 constitute the coplanar transmission line structure, and, the signal electrode 51 of the upper electrode and the lower shielding ground electrode layer 50G-2 constitute the microstrip line structure, so the full constitution is also called the hybrid of CPW and microstrip line. The left upper figure shows the parallel-connected filter unit circuit. The operation of the full filter is described as follows: the signal is input to the input port 50, and passing the first resonator formed with the upper electrode 51, the first piezoelectric unit R1 and the upper electrode 52, and then connect to the output port 50′ by passing the second resonator formed with the upper electrode 52, the second piezoelectric unit R2 and the upper electrode 52′. In addition, the first resonator is shunt connected with the third resonator formed with the upper electrodes 52 and 53, the third piezoelectric unit R3 and the ground electrode 50G-1, and, connect in shunt with the fourth resonator formed with the upper electrodes 52′ and 54, the fourth piezoelectric unit R4 and the ground electrode 5OG-1. Then to attain the series connection between the first resonator and the second resonator and the shunt construction of the third resonator and the fourth resonator, and make sure the input port 50 and the output port 50′ are laid in the same layer to benefit the back-end process or package and the wafer scale measurement. Besides, by using the construction of the hybrid of CPW and microstrip line filter, the high frequency parasitic effect of the substrate or bottom-supporting layer is lowered and the noise on the wafer level measurement is decreased.

Besides, in order to improve the skirt selectivity or the skewing factor of the filter, it could adopt the multi-stage ladder-type filter construction. The FIG. 6 shows the fifth embodiment of present invention to use in the hybrid of CPW and microstrip line to constitute the four-stage ladder-type filter construction, then the coplanar electrode is provided. The left lower figure of the FIG. 6 is the side view of the filter device, referring to the figure, it can be seen that the filter device is divided into three layers from the top to bottom: the first layers are the shielding ground electrode layer 60G-2, the second layers are the piezoelectric units R1, R2, R3, R4, R5, R6 and R7, and the third layers are the upper electrode layers composed with the signal electrode 61 and the two sides ground electrode 60G-1 that both included coplanar transmission line construction. The right figure of the FIG. 6 is the each layer's dissection corresponding to the filter device, which is explicitly showing the electrode outlines and connections. Referring to the side view, it is shown that the signal electrode 61 and the two sides ground electrode 60G-1 constitute the coplanar transmission line construction, and the signal electrode 61 of the upper electrode and the lower shielding ground electrode layer 60G-2 constitute the microstrip line construction, so, the full construction is also called the hybrid of CPW and microstrip line. The left upper figure shows the parallel-connected filter circuit. The operation of full filter is described as follows: the signal is input to the input port 60, and passing the first resonator formed with the upper electrode 61, the first piezoelectric unit R1 and the upper electrode 62, and then connect to output port 60′ by passing the three series of the second resonator formed with the upper electrode 62, the second piezoelectric unit R2 and the upper electrode 63, and the third resonator formed with the upper electrode 63, the third piezoelectric unit R3 and the upper electrode 66, and the fourth resonator formed with the upper electrode 64, the fourth piezoelectric unit R4 and the upper electrode 64′. In addition, the first resonator could shunt with the fifth resonator formed with the upper electrodes 62 and 65, the fifth piezoelectric unit R5 and the ground electrode 60G-1, and parallel-connected with the sixth resonator formed with the upper electrodes 63 and 66, the sixth piezoelectric unit R6 and the ground electrode 60G-1, and parallel-connected with the seventh resonator formed with the upper electrodes 64 and 67, the seventh piezoelectric unit R7 and the ground electrode 60G-1, and parallel-connected with the eighth resonator formed with the upper electrodes 64′ and 68, the eighth piezoelectric unit R8 and the ground electrode 60G-1. Then to attain the series connection between the first resonator, the second resonator, the third resonator and the fourth resonator and the shunt architecture of the fifth resonator, the sixth resonator, the seventh resonator and the eighth resonator, and make sure that the input port 60 and the output port 60′ are laid in the same layer to benefit the back-end process or package and the wafer scale measurement. As foregoing description, using the architecture of the hybrid of CPW and microstrip line filter, the high frequency parasitic effect of the substrate or bottom-supporting layer is lowered and the noise on the wafer scale measurement is decreased.

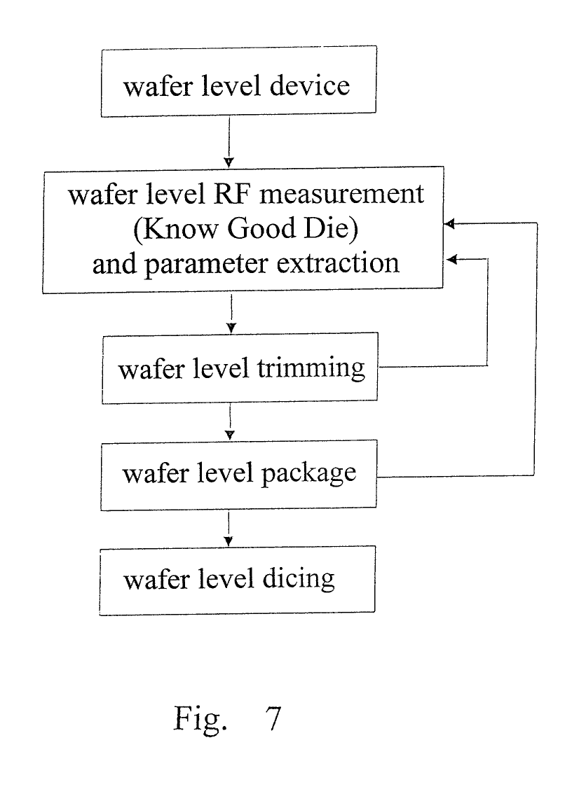

The FIG. 7 shows a flow chart relating to the present invention that use the wafer level chip scale package (WLCSP) technique to apply in the bulk acoustic wave filter device. After the full on-wafer device is completed, the full-automatic or semi-automatic wafer scale RF measurement is firstly performed in order to obtain the fine device distribution and the extraction of the high frequency parameters, and then the wafer trim of the deviation item of the frequency or bandwidth is then performed, and the wafer scale RF measurement is repeated until completely trimming. And then, do the wafer scale package, and owing to the accompanying high frequency parasitic effect, there must extract by the wafer scale RF measurement, after that, feasible trimming is performed. After the measurement is completed, then dicing is performed. Owing to the package is completed before dicing, not only the floating construction would be protected but also the yield would be decreased. With regard to the high frequency parasitic effect of the package, there would have the more correct high frequency parameters if the high frequency measurement is performed after the package. In general, if the measurement is performed after the dicing and package, then it could not performed the coplanar wafer level RF measurement of much more saving time and cost. Besides, it is relatively easy and save time if the full wafer scale trimming has to be performed, and, it could rapidly and exactly measure the high frequency parasitic effect of the package, and it could do the high frequency measurement and trimming of the full wafer scale before or after the package, and it could relatively decrease the time and cost to the package and measure.

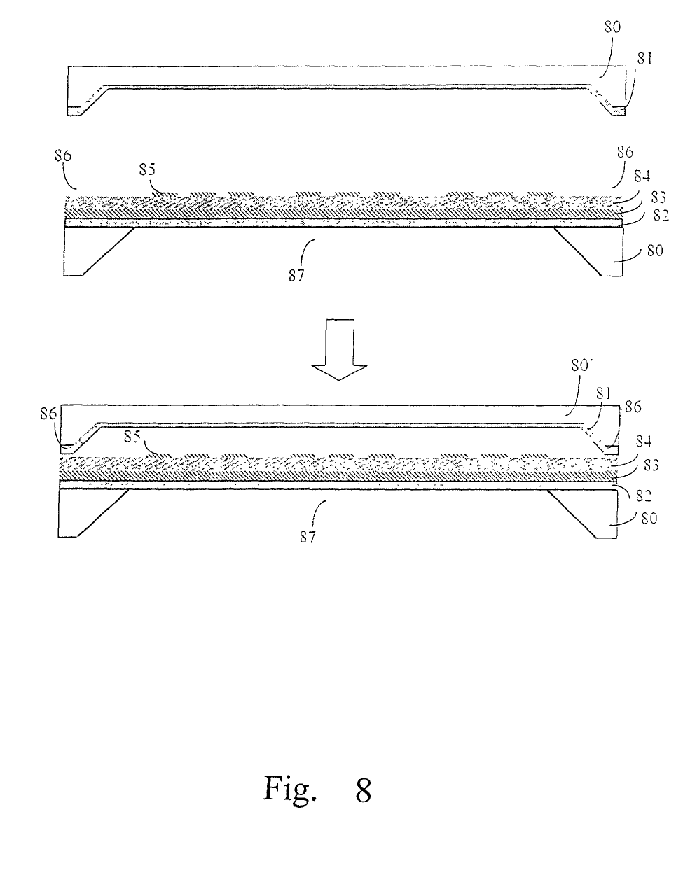

FIG. 8 shows the sixth embodiment using the wafer level chip scale package (WLCSP) technique to constitute the bulk acoustic wave filter construction. As shown in FIG. 8, the full wafer involving filters contains the substrate 80, the supporting layer 82, the lower electrode layer 83, the piezoelectric layer 84, the upper electrode layer 85 and the cavity 87. And the upper cover to be used in the wafer level scale package includes the substrate 80′ and the metal layer 81 to be used for shielding. And then, connect the wafer involving the filter and the upper cover of the wafer scale package at connector 86 wherein the filter device construction of the wafer can be even order ladder-type the series and parallel-connected filter, or a lattice filter constituted by connecting the series and shunt four resonators and the multistage filter constitution constituted by hybrid of CPW and microstrip line.

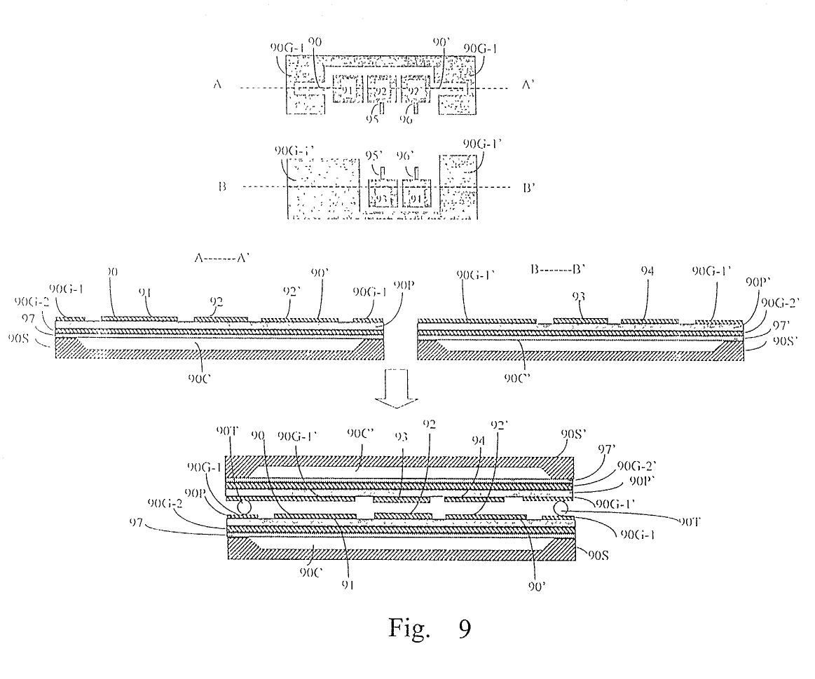

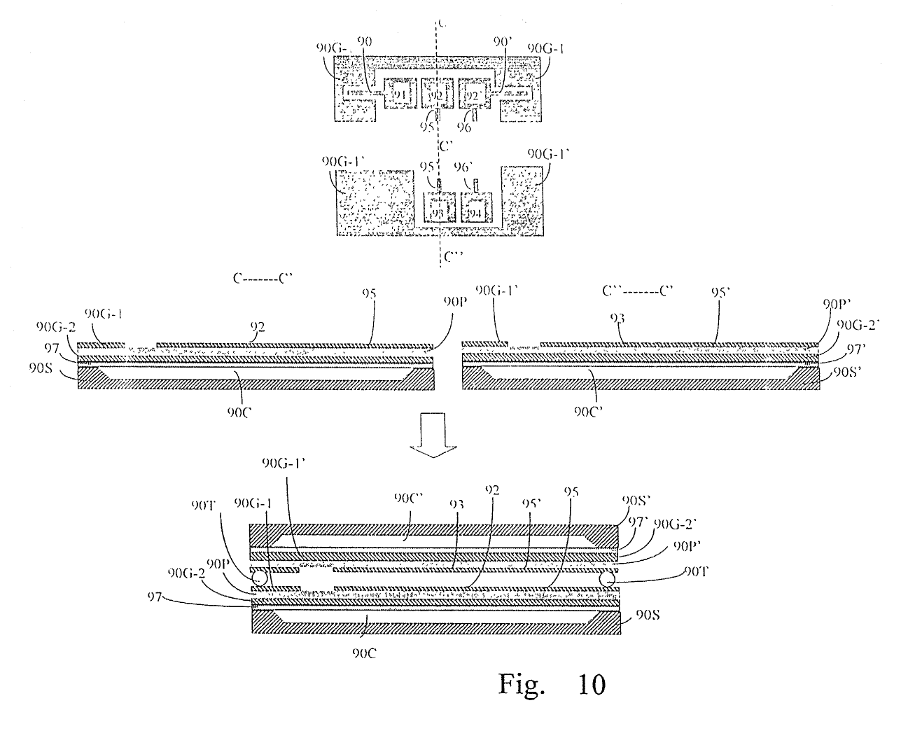

FIG. 9 is a cross-sectional view along line AA′ and line BB′ showing the seventh embodiment using the wafer level chip scale package (WLCSP) technique to combine the series resonator and the shunt connected resonator to constitute the bulk acoustic wave filter construction. As shown in FIG. 9 the full wafer involving the filter contains the substrate 90S, the supporting layer 97, the lower electrode layer 90G-2, the piezoelectric layer 90P, the upper electrode layer 90, 91, 92, 92′, 90′ and the cavity 90C. And the upper cover to be used in the wafer level scale package involves the substrate 90S′, the supporting layer 97′, the lower electrode layer 90G-2′, the piezoelectric layer 90P′, the upper electrode layer substrate 90G-l′, 93, 94 and the cavity 90C′. Wherein the series resonator is involved in the lower substrate 90S and the shunt connected resonators involved in the upper substrate 90S′, and by the technique of wafer level package, the series resonator and the shunt resonator are connected at connector 90T, and make the ground electrode 90G-1 of the series resonator and the ground electrode 90G-l′ of the shunt resonator commonly connected to the same ground electrode. It not only can decrease the filter device area but also can separately handle the piezoelectric layer 90P thickness of the series resonator and the piezoelectric layer 90P′ thickness of the shunt resonator to attain the better performance of the filter device. Besides, the lower electrode layer 90G-2 of the series resonator and lower electrode layer 90G-2′ of the shunt resonator could provide the well shielding metal layer of the full filter device.

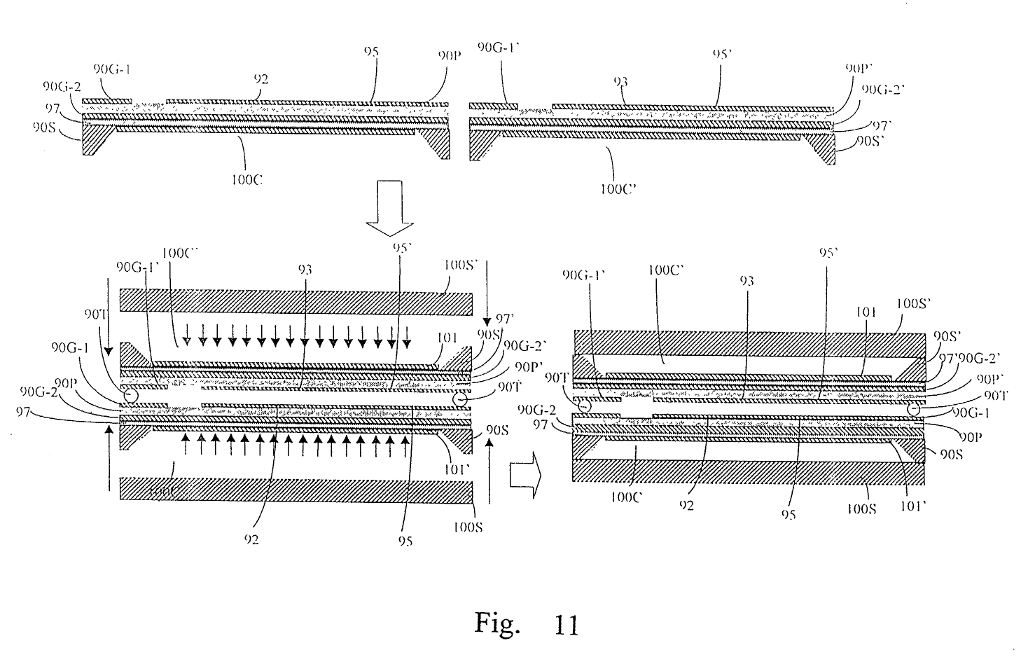

FIG. 10 is a cross-sectional view along the line CC′ showing the seventh embodiment using the wafer level chip scale package (WLCSP) technique to combine the series resonator and the shunt connected resonator to constitute the bulk acoustic wave filter constitution. Referring to the figure, it is clearly seen that by wafer level chip scale package technique the series resonator and the shunt resonator can be connected at connectors 90T, 95, 95′, 96 and 96′ so as to attain the micro-type bulk acoustic wave filter device.

FIG. 11 is a cross-sectional view showing to the eighth embodiment using in the wafer level chip scale package (WLCSP) technique to combine the series resonator and the shunt resonator to constitute the bulk acoustic wave filter construction and to trim. As shown in FIG. 11, the full wafer involving the filter contains substrate 90S, the supporting layer 97, the lower layer 90G-2, the piezoelectric layer 90P, the upper electrode layer 90G-1, 92, 95 and the cavity 100C. And, the upper cover to be used in the wafer level scale package involves the substrate 90S′, the supporting layer 97′, the lower layer 90G-2′, the piezoelectric layer 90P′, the upper electrode layer substrate 90G-l′, 93, 95 and the cavity 100C′. Wherein the series resonator is involved in the lower substrate 90S and the shunt resonator is involved in the upper substrate 90S′, and by the technique of wafer scale package the series resonator and the shunt resonator are connected at connector 90T, and make the ground electrode 90G-1 of the series resonator and the 90G-1′ of the shunt resonator commonly connected to the same ground electrode. And then, the supporting layer 97 of the series resonator and the supporting layer 97 of the shunt resonator can be removed by etch method, or, more deposit the trim layer 101 and 101′ to the supporting layer 97 of the series resonator and the supporting layer 97 part of the shunt resonator by deposition method to adjust the frequency and bandwidth of the filter device. And, owing to the series resonator and the shunt resonator are not coplanar, so the series resonator part or the shunt resonator part can be separately trimmed to attain the optimum frequency and bandwidth. The filter resonator frequency of the resonator is approximately determined by formula I.

f≈(dₚ/Vₚ+dₘ/Vₘ+dₛ/Vₛ) (formula I)

Wherein dₚ, dₘ and dₛ are the acoustic wave passing path including the piezoelectric material, the metal electrode layer thickness and the supporting layer thickness of the filter, while the Vₚ, Vₘ and Vₛ are the corresponding material acoustic velocity. Accordingly the trim layer 101 and 101′ could be selected as the dielectric layer or the metal layer to trim the frequency depending on the demand. And if the trim layer 101 and 101′ are selected as the dielectric layer that has the opposite temperature coefficients of frequency (TCF), e.g. Silicon Dioxide, then the proportion between the trim layer 101, 101′ and the piezoelectric layer 90P, 90P′ can be adjusted to attain the frequency trim. This full wafer level trimming not only can repeat to do the high frequency measure until complete trim but also the trim is reversible, and it would not affect the pattern of the upper electrode. After the measurement is completed, the upper cover 100S and lower cover 100S′ are added to protect the device, and then to dice it. Since the device is package before dicing, it still could remove the upper cover 100S and the lower cover 100S′ perform the trim. And, owing to the package is completed before the dicing, so it not only can protect the suspended structure but also can increase the yield. With regard to the high frequency parasitic effect of the package, there would have the more correct high frequency parameters if the high frequency measurement is performed after the package. In general, if the measurement is performed after the dicing and package, then it can not perform the coplanar wafer level RF measurement of much more saving time and cost. Besides, it is relatively easy and save time if the full wafer scale trimming has to be performed, and, it could rapidly and exactly measure the high frequency parasitic effect of the package, and it could do the high frequency measurement and trimming of the full wafer scale before or after the package, and it could relatively decrease the time and cost to the package and measure.

What is claimed is:

1. A bulk acoustic wave ladder-type filter involving the lower electrode layer, the piezoelectric unit layer and the upper electrode layer, characterized in that:
the full filter includes: a first resonator formed by an input port for inputting a signal, an upper electrode, an first piezoelectric unit and the lower electrode;
a third resonator formed with a first connector, a lower electrode, a third piezoelectric unit and an upper electrode;
a second resonator connected series with the first resonator, it is formed with the lower electrode, the second piezoelectric unit and the upper electrode;
a fourth resonator formed with a second connector, the upper electrode, a fourth piezoelectric unit and a lower electrode;
the first resonator is series connected with the second resonator, and, is connected in shunt with the third resonator and the fourth resonator; the input port and the output port are laid in the same layer to benefit the backend process or package and the wafer level measurement.

2. The filter according to claim 1, wherein the order of the ladder-type could be even number as two, four etc.

3. A bulk acoustic wave lattice filter involving the lower electrode layer, the piezoelectric unit layer and the upper electrode layer, characterized in that: the full filter unit including:
a first resonator formed by an input port for input signal, and the upper electrode, a piezoelectric layer, a lower electrode, for passing signal and let it back to the upper electrode, an output port is also provided;
a second resonator formed with the upper electrode, the piezoelectric layer, the lower electrode, the piezoelectric layer for the signal to pass and back to the upper electrode, an output port is also provided;
a third resonator formed with the upper electrode, the piezoelectric layer, the lower electrode, the piezoelectric layer for the signal to pass and back to the upper electrode, an output port is also provided;
a fourth resonator formed with the upper electrode, the piezoelectric layer, the lower electrode, the piezoelectric layer for the signal to pass and finally back to the upper electrode, an output port is also provided.

4. A two stage ladder-type filter constructed by a hybrid of CPW and microstrip line involving the lower shielding ground electrode layer, the piezoelectric layer and the upper electrode layer, characterized in that: a full filter unit including:
an input port for inputting signal;
a first resonator that is formed with the upper electrode, a first piezoelectric unit and an upper electrode;
a second resonator formed with the upper electrode, the second piezoelectric unit and the upper electrode;
said first resonator is connected in series with the second resonator and then connects to an output port;
a third resonator formed with an upper electrodes, a third piezoelectric unit and a ground electrode; and
a fourth resonator formed with an upper electrodes, a fourth piezoelectric and a ground electrode; siad first resonator is connected in shunt with said third resonator and said forth resonator.

5. The filter structure according to claim 4, wherein the signal electrode of the upper electrode and the two sides ground electrode constitute a coplanar transmission line structure, and the signal electrode of the upper electrode and the lower shielding ground electrode layer constitute a microstrip line construction.

6. The filter according to claim 4, wherein the two stage ladder-type is a multi-stage ladder-type filter constitution.

7. A packaging of a bulk acoustic wave filter involving the steps of:
completing the full wafer level device;
performing wafer level RF measurement;
performing wafer level trim;
performing wafer level package;
repeating an wafer level RF measurement;
performing wafer level package; and then dicing.

8. The packaging of a bulk acoustic wave filter device according to claim 7, wherein the bulk acoustic wave filter device comprises:
a filter of wafer involving a substrate, a supporting layer, a lower electrode layer, a piezoelectric layer, an upper electrode layer and a cavity;
an upper cover to be used in a shielding metal layer for an upper cover of a wafer scale package;
said a filter of wafer and upper cover of a wafer scale package is connected at a connector.

9. The packaging according to claim 8, wherein the filter device construction to a wafer involving a filter device could be a even order ladder-type combining with series and shunt connected filter.

10. The packaging according to claim 8, wherein said filter device construction to a wafer involving a filter device could be four series and shunt resonators to constitute a lattice filter.

11. The packaging according to claim 8, wherein said filter device conctruction to a wafer could be a hybrid of CPW and a microstrip line to constitute a multi-stage filter.

12. A package of a bulk acoustic wave filter device, wherein the bulk acoustic wave filter device involving:
a filter of wafer composed of a lower substrate, the supporting layer, a lower electrode layer, a piezoelectric layer, a upper electrode layer and a cavity;
an upper cover of wafer scale package composed of an upper substrate, a supporting layer, a lower electrode layer, a piezoelectric layer, a upper electrode layer and a cavity;
said filter of wafer and said upper cover of a wafer scale package is connected at a connector; and both are merged by an wafer scale package.

13. The package according to claim 12, wherein a series resonator is involved in a lower substrate and a shunt resonator is involved in an upper substrate part.

14. A package according to claim 12, wherein the ground electrode of the series resonator is connected with a ground electrode of a shunt resonator so as to obtain a common connect to the same ground electrode.

15. A packaging of a bulk acoustic wave filter device, wherein the wafer level chip scale package (WLCSP) technique is used for combining the series resonator and the shunt resonator to constitute the bulk acoustic wave filter constitution and then performing the trimming, including steps of:
providing a filter of wafer composed of a lower substrate, a supporting layer, a lower electrode layer, a piezoelectric layer, an upper electrode layer and a cavity;
providing an upper cover of wafer scale package composed of an upper substrate, a supporting layer, a lower electrode layer, a piezoelectric layer, an upper electrode layer and a cavity;
merging said filter of wafer and upper cover by wafer scale package; changing a supporting layer thickness or adding a trim layer to trim a wafer level scale;
adding an upper cover to protect device; and then dicing.

16. The packaging according to claim 15, wherein a series resonator is involved in a lower substrate and a shunt resonator is involved in an upper substrate part.

17. The packaging according to claim 15, wherein the ground electrode of the series resonator is connected with a ground electrode of a shunt resonator so as to obtain a common connect to the same ground electrode.

18. The packaging according to claim 15, wherein the supporting layer part is removed by etch method

19. The packaging according to claim 15, wherein a trim layer is deposited to said supporting layer by deposition method to adjust the frequency and bandwidth of a filter device.

20. The packaging according to claim 15, wherein said trim layer can be selected as a dielectric layer or a metal layer for trimming the frequency.

21. The packaging according to claim 15, wherein said trim layer is selected as a dielectric layer that has the opposite temperature coefficients of frequency (TCF), e.g. Silicon Dioxide, such that the proportion between a trim layer and a piezoelectric layer can be adjusted to attain the frequency trimming.
